(19) United States
(12) Patent Application Publication
(10) Pub. No.: US 2013/0106245 A1
(43) Pub. Date: May 2, 2013

(54) FIBRE COMPOSITE COMPONENT ACTING AS AN ACTUATOR, A SENSOR AND/OR A GENERATOR AND METHOD FOR THE PRODUCTION THEREOF

(71) Applicants: Andreas Giebe, Freital (DE); Thomas Roedig, Freital (DE); Andreas Schoenecker, Freital (DE); Uwe Scheithauer, Dresden (DE)

(72) Inventors: Andreas Giebe, Freital (DE); Thomas Roedig, Freital (DE); Andreas Schoenecker, Freital (DE); Uwe Scheithauer, Dresden (DE)

(21) Appl. No.: 13/643,710

(22) PCT Filed: Apr. 26, 2011
(86) PCT No.: PCT/DE11/00465

§ 371 Date: Jan. 3, 2013

(30) Foreign Application Priority Data
Apr. 28, 2010 (DE) 10 2010 019 666.5

(51) Int. Cl. H01L 41/08; H01L 41/25

(52) U.S. Cl. CPC H01L 41/082; H01L 41/25
USPC 310/340; 29/25.35

(57) ABSTRACT

The invention relates to fiber-reinforced composites acting as an actuator, as a sensor and/or as a generator and to a manufacturing process. It is the object of the invention to provide such fiber-reinforced composites which can be manufactured simply and reliably and which are securely fastened and exactly positioned as elements acting as actuators, generators and/or sensors. In a fiber-reinforced composite in accordance with the invention, at least one piezoelectric element is fixed and positioned by fibers or yarn within a fiber structure or by means of fibers or yarn to a fiber structure. Flexible, electrically conductive connections which can be contacted from outside the fiber-reinforced composite are led at and/or within the fiber structure to electric connector contacts of the at least one piezoelectric element. One or more piezoelectric elements, electrically conductive connections and the fiber structure are embedded in a matrix material.

The invention relates to fiber-reinforced composites acting as an actuator, as a sensor and/or as a generator and to a manufacturing process. Fiber-reinforced composites are used in lightweight construction due to their advantageous mechanical properties and in particular to their higher specific strengths. In this respect, the strength of a matrix material is increased over acting tensile and compressive forces with the aid of a fiber structure embedded therein. The deadweight increases in this respect only slightly if at all. As a rule, the total mass is even smaller in relation to the mass of the matrix material.

GRP composites or CRP composites are thus equally used for a variety of applications as is the case with components in which concrete is used as the matrix material.

It is, however, also desired with such composites to be able to carry out a state monitoring or an active influencing. In particular piezoelectric elements are inter alia suitable for this. Acting forces, deformations and also sound waves can be detected at a component using them. In addition to the sensor properties of such piezoelectric elements, their actuator properties are, however, also used or their use is desired.

Piezoelectric elements have previously been fastened to fiber-reinforced composites in that they are fastened thereto with material continuity by adhesive bonding. Such a bond connection is, however, only suitable with limitations since a complete, direct transmission of forces is not possible with it since a certain degree of elasticity of the used adhesive is necessary to avoid any peeling of a piezoelectric element thus fastened. In this respect, piezoelectric elements can only be fastened where an access is possible.

A better connection can be achieved in that a receiver for a piezoelectric element is formed by removal of material at a fiber-reinforced composite and in that said piezoelectric element can additionally be fixed with shape matching in said receiver. It is obvious that a substantial interfering point thereby arises at a fiber-reinforced composite which substantially impairs the strength.

In both mentioned cases, it is moreover a disadvantage that the fastening positions at the fiber-reinforced composite have to be accessible from the outside or at least two parts have to be connected to one another by joining for the manufacture of a fiber-reinforced composite subsequent to a fastening of a piezoelectric component.

A special protection against external influences is required for piezoelectric elements and for the electrically conductive connections led to them.

It is therefore the object of the invention to provide fiber-reinforced composites having an action as an actuator, as a generator and/or as a sensor which are simple and reliable in manufacture and which are fastened securely and positioned exactly as actuators, generators and/or sensors.

In accordance with the invention, this object is achieved by a fiber-reinforced composite having the features of claim 1. It can be manufactured using a method in accordance with claim 11. Advantageous embodiments and further developments of the invention can be realized using technical features designated in the subordinate claims.

In a fiber-reinforced composite in accordance with the invention acting as an actuator, as a generator and/or as a sensor, at least one piezoelectric element is fixed and positioned by fibers or yarn within a fiber structure or by means of fibers or yarn at a fiber structure. In addition, a flexible, electrically conductive connection which can be contacted from outside the fiber-reinforced composites is led at and/or within the fiber structure to electric connector contacts of the at least one piezoelectric element. The one or more piezoelectric elements, electrically conductive connections and the fiber structure are embedded in a matrix material.

Materials customary for fiber-reinforced composites such as polymers (resins, thermosetting or thermoplastic polymers) or concrete can be used as the matrix material. It can also be a polymer concrete.

The usual fiber materials can likewise be used for the fibers. The fiber structure can in this respect be manufactured from pure fibers or also from fibers further processed to yarns using the known textile manufacturing processes.

As a woven fabric, crocheted fabric, meshwork, non-crimp fabric or knitted fabric, a fiber structure can, for example, form a semi-finished textile product, optionally in the form of a textile, areal fabric. In this respect, fibers can also be connected to one another with material continuity, which can be achieved e.g. by adhesive bonding or welding.

In accordance with the invention, piezoelectric element(s) can be woven into the fiber structure, can be twisted therein, laid therein and/or be fastened thereto by a sewing or stitching connection. This can also be the case with the electrically conductive connections. Electrically conductive yarns, wires or strands of mutually twisted thin wires can be used for this purpose.

A fixing of piezoelectric elements at a fiber structure is, however, also possible in that at least one piezoelectric element is introduced into at least one receiver formed at the textile fiber structure in the form of a loop or pocket and is thereby already fixed at/in the fiber structure in shape-matched manner before the matrix material is subsequently hardened, melted and reconsolidated (with thermoplastic polymers) or completely polymerized. A matrix material can in this respect also be infiltrated after the introduction of piezoelectric elements or can be injected into a correspondingly prepared molding tool.

Piezoelectric elements are therefore integrated into the fiber structure or fastened thereat with fibers or yarn. They can immediately be worked into the fiber structure, for example co-woven into it, on the manufacture thereof. The same also applies to the electrically conductive connections. In this case, the positioning and fixing can be achieved in one step.

There is, however, also the possibility to fasten one or more piezoelectric elements at a fiber structure which has already been manufactured in a textile manufacturing process and which can be provided in the form of a textile surface, which can be achieved by sewing on or stitching on. In this respect, the electrically conductive connections led to connector contacts of the piezoelectric elements can be correspondingly fastened simultaneously. An electrically conductive embroidery thread or sewing thread can be used for this purpose.

Connector contacts of the piezoelectric elements can be obtained by simple regional removal of an insulating layer. An electrically conductive connection such as a metallic wire can be fastened to or in the fiber structure such that it directly contacts a connector contact and the electrically conductive connection can thus be achieved.

In the invention, piezoelectric elements formed as fibers can be used particularly advantageously. They can be co-processed particularly favorably due to their shape. However, a good use is also possible due to shape. Preferred directions of action can be taken into account both on use as an actuator and as a sensor. In this respect, the mechanical loads of a fiber-reinforced composite can be taken into account in which frequently recurring influences occur which are the same or similar. At least one region of a fiber-reinforced composite which is exposed to the highest load can also be provided with piezoelectric elements to be able to carry out a state monitoring in which defects which have occurred can be recognized and/or in which conclusions can be drawn on the still available residual service life. Piezoelectric elements formed as fibers are characterized by a high aspect ratio (length to thickness). The cross-section geometry can be selected as matched to the respective application of a fiber-reinforced composite. No circular or oval cross-section therefore necessarily has to be observed in the fibers. The selection can be made independently of the cross-section.

Piezoelectric elements can also form a series arrangement at a fiber-reinforced composite. With piezoelectric fibers, their longitudinal axes should each be aligned parallel to one another. Larger regions of a fiber-reinforced composite can thereby be monitored or influenced in the manner of an actuator in the same way. Fibrous piezoelectric elements can, however, also be aligned in a common axis with their longitudinal axes so that a larger length in this axial direction can be taken into account.

A plurality of fibrous piezoelectric elements can in this respect additionally be sheathed by fibers and/or a material so that the piezoelectric elements thus mutually connected form a correspondingly extended contiguous piezoelectric element. In this respect, connector contacts can be present or exposed at each individual one of the piezoelectric elements thus strung together so that each of the piezoelectric elements is individually contacted and is accordingly individually usable. With a corresponding electric connection, however, all or at least a plurality of these piezoelectric elements can, however, be used together or also simultaneously in the same manner. A sheath can be formed by winding around with thread material or yarn material, by a coating or by enclosing in a tubular structure. A sheath can extend over the total length of the piezoelectric elements to be connected to one another. In regions in which two piezoelectric elements touch or overlap, a sheath can also be formed in reinforced form and have a greater strength than in regions disposed therebetween. Electrically conductive connections can also be led from one piezoelectric element to other piezoelectric elements within the sheath.

Connector contracts via which, for an action as an actuator, voltage can be supplied or, for an action as a sensor or as a generator, electric energy can be led off, can be present at regular intervals or irregular intervals at piezoelectric elements. Connector contacts can, for example, be obtained by locally limited removal of a dielectric coating from a piezoelectric element. With fibrous piezoelectric elements, connector contacts can be made in ring shape or with a plurality of segments over the periphery. With connector contacts arranged next to one another, a supply or leading off of electric voltage can take place with an electric potential difference or as electrically positive and negative voltage.

Piezoelectric elements formed as hollow fibers can be embedded in an electrically conductive matrix material. There is also the possibility of using an electrically conductive fiber structure alone or additionally for an electric contacting. For this purpose, at least individual fibers, e.g. carbon fibers, of the fiber structure can be electrically conductive or coated in this manner. In this respect, an electrically conductive connection can be led to and/or through the hollow space of the hollow fiber and can be electrically conductively contacted with an electric pole at the respective piezoelectric element. The inner jacket surface or a part thereon can form an electrical connector contact of a piezoelectric element formed as a hollow fiber. An electrically conductive connection to the correspondingly other electric pole can be established to a connector contact present at the outer jacket of the hollow fiber by mean of an electrically conductive connection, as already mentioned, or with a sufficient electric conductivity, via the electrically conductive matrix material.

In this respect, an action as an actuator can then be achieved by applying an electric voltage and an extension of a piezoelectric element resulting therefrom which in turn result in a deformation of and/or in the introduction of mechanical voltages into the fiber-reinforced composite. Sound waves can, however, thus also be emitted and then detected by sensors. The action as an actuator can be influenced by varying the electric voltage applied. This can inter alia relate to the frequency and amplitude.

In the invention, there is also the possibility of leading off via contacts and utilizing the electric voltage obtained on a deformation/vibration by means of the piezoelectric elements. In this respect, the electric energy can also be stored and later used in a suitable and electrically connected electrical energy storage element.

With sound waves propagating at the fiber-reinforced composite by acting forces and/or moments and or propagating in the fiber-reinforced composite, a proportional electric voltage can be generated at a piezoelectric element and can be picked up and measured via the electrically conductive connections. In this respect, a piezoelectric element forms a sensor or generator.

It is favorable for many applications to arrange piezoelectric elements in the fiber-reinforced composite in one plane which is arranged outside the neutral fiber of the fiber-reinforced composite.

Amplification effects, for example for a deformation or detection, can be utilized by the asymmetry with respect to this plane which can thus be achieved by the respective spacing of the planes in which a piezoelectric element is arranged with respect to the neutral fiber.

It is possible to proceed on the manufacture of fiber-reinforced composites in accordance with the invention such that at least one piezoelectric element is fastened by fibers or by yarn by means of a textile manufacturing process in the fiber structure or by a sewing or stitching connection at the fiber structure. Electrically conductive connections are led to the electric connector contact(s) present at the piezoelectric element(s) and subsequently the fiber structure thus prepared is embedded in a matrix material within a mold tool and the matrix material is then hardened.

There is the possibility for large components to connect a plurality of fiber structures already manufactured using a textile manufacturing process and in which at least one piezoelectric element is correspondingly fixed at at least one fiber structure to one another by a textile process. This can e.g. take place by sewing or stitching. In addition to the possibility of establishing the connection of a plurality of fiber structures in a shape matched manner using a textile process, there is the possibility of also achieving this with material continuity, e.g. by adhesive bonding.

As already initially addressed, a fiber structure, adapted to the demands of the respective fiber-reinforced composite, can be produced using the different known manufacturing processes. In this respect, it can also be possible, for example on weaving, to co-process piezoelectric elements and to form the fiber structure in a manufacturing step and simultaneously to fix piezoelectric elements in the fiber structure by weaving in. In this case, piezoelectric elements advantageously formed as fibers can be woven in. In the same manufacturing step, the electrically conductive connections can also be co-woven in and in this respect be positioned with respect to connector contacts at piezoelectric elements and be fixed by means of the woven fiber structure before the embedding is carried out in the matrix material.

In particular when fiber structures other than woven ones are used for the manufacture of fiber-reinforced composites, it is also suitable to fasten piezoelectric elements to a previously manufactured fiber structure using threads or yarn. It is therefore simply sewn or stitched on, with the most varied stitch forms being able to be used for the sewing on or stitching on. In this respect, however, a fixing of the piezoelectric elements in all directions should be achieved wherever possible. It is advantageous in this respect simultaneously to sew or stitch electrically conductive connections onto the respective piezoelectric element at the same positions. A knot with crossed or overlapping fibers or yarn is so-to-say formed there and electrically conductive connections can be positioned with the connector contacts of piezoelectric elements and fixed there.

A fiber structure with a fixed piezoelectric element and electrically conductive connections prepared in this manner can be inserted into a molding tool and the matrix material can then be injected or poured in. Different processes can be used. In addition to a simple dead-mold casting, a die-cast mold process or a centrifugal casting process can be used for the manufacture.

There is also the possibility, in particular for polymers as the matrix material, to manufacture fiber-reinforced composites by injection molding. The RTM (resin transfer molding) process can be used particularly advantageously. In this respect, work can be carried out in the mold tool in a vacuum and the matrix material can infiltrate into hollow spaces of the fiber structure. In addition, open pores, hollow spaces and delaminations can be avoided.

A fiber-reinforced composite in accordance with the invention can also be manufactured in that at least two laminate layers or areal textile structures are manufactured as intermediate products and subsequently the laminate layers are connected to one another by hot pressing with one another with material continuity. In this respect, the laminates can be manufactured with a fiber structure and a not completely hardened or thermoplastic polymer as a matrix material. At least one laminate layer is used into which at least one piezoelectric element is integrated, that is, is connected to the fiber structure. The laminate layers present as intermediate products can then be stacked in a desired form, sequence and alignment and can be connected to one another in a press at elevated pressure and elevated temperature. Suitable resins, thermosetting or thermoplastic polymers, can be used as the matrix material.

A fiber can be impregnated with a polymer and/or a polymer can be infiltrated into the fiber structure for the manufacture of a laminate, as an intermediate product, with the polymer not being completely hardened or polymerized. Hybrid yarns can particularly advantageously be used for the manufacture of a textile fiber structure. They can be formed from reinforcement fibers and fibers formed from thermoplastic polymer. The polymer of the hybrid yarns can then form at least a part of the matrix material. A fiber structure can be manufactured wholly, regionally or partially from a hybrid yarn.

An intermediate product can also be used so that matrix material depots are present, in particular in regions in which piezoelectric elements are to be fixed. The fiber/yarn portion there is smaller than the matrix material portion. A complete enclosure of piezoelectric elements in the matrix material can thereby be achieved.

Since the piezoelectric elements can be sufficiently fixed in the desired positions and in the desired alignment using the already named possibilities in/at the fiber structure, their position also varies only negligibly, if at all, in casting or injecting the matrix material although in this respect correspondingly high forces act as a consequence of the flowing movement of the correspondingly viscous matrix material. In contrast to an adhesive bonding of piezoelectric elements onto a fiber structure, a slipping or peeling can be avoided and a secure, permanent adhesion can be achieved. Delaminations such as are critical on adhesive bonding do not occur.

In addition, the fiber structure with the matrix material forms a support structure which can avoid a breaking of the piezoelectric elements, which are brittle as a rule, during operation and manufacture.

With the invention, reinforced-fiber composites can be provided in which piezoelectric elements are integrated and are positioned very exactly in so doing. They are protected against environmental influences by the matrix material. They can be arranged at positions inaccessible from the outside in the completely manufactured reinforced-fiber composite and can in this respect be completely embedded in the matrix material. Different electric interconnections, e.g. in the form of ring electrodes, serial or parallel circuits or a connection to collectors or also a separate control or a separate pick-up of individual piezoelectric elements are possible using the electrically conductive connections. The known advantages of reinforced fiber structural elements are maintained and their possibilities of use can be extended by the use of piezoelectric elements.

A fiber structure still without a matrix material can be brought into form simply and in a short time by cutting, stamping or by another suitable separation process. In this respect, holes can also be formed.

In addition to an already explained jacketing, a protective layer can also be formed on piezoelectric elements. In this respect, the connector contacts should, however, remain accessible and be kept free.

In particular when piezoelectric elements are used in the form of fibers, they form interference points which can be neglected in the fiber composite which impair its properties negligibly negatively, which in particular applies to the strength.

Reinforced fiber components can, however, also be used for gaining electric energy since the electric voltage generated on deformation using piezoelectric elements can be supplied for utilization. It can be temporarily stored in a connected, suitable element storing electric energy.

Individual or several piezoelectric elements combined to form groups can be arranged, separated from one another locally, at a reinforced-fiber composite in accordance with the invention and in so doing form sensitive regions or regions acting as an actuator as “islands”.

Reinforced-fiber composites in accordance with the invention can be manufactured with large areas and/or in large volumes. Their use can take place in many technical applications. They can, for example, be used as lightweight components for wind turbines and in automotive construction. In the construction industry, concrete composites can be used for building monitoring or also in transport route engineering. In the latter case, traffic censuses can, for example, be provided using such composites or sensor elements for traffic management can be provided.

The invention will be explained in more detail by way of example in the following.

There are shown:

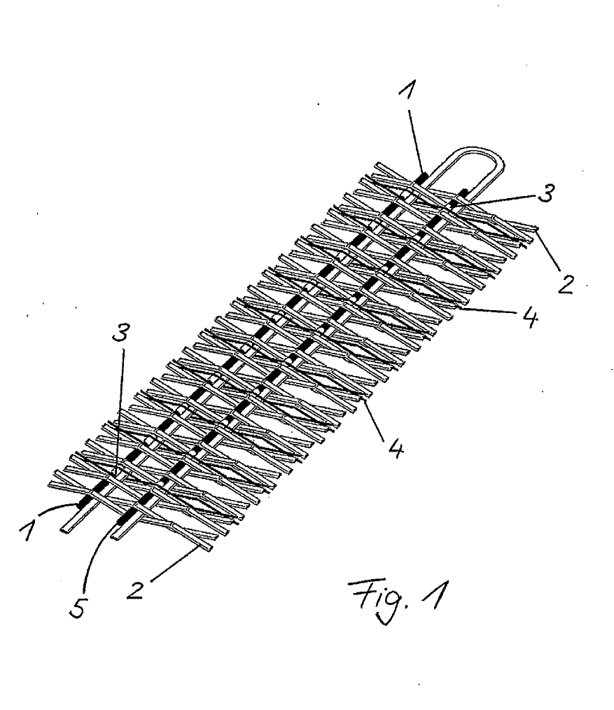

FIG. 1: in schematic form, fibrous piezoelectric elements which can be integrated into a fiber structure or fastened thereto with copper wires as electrically conductive elements.

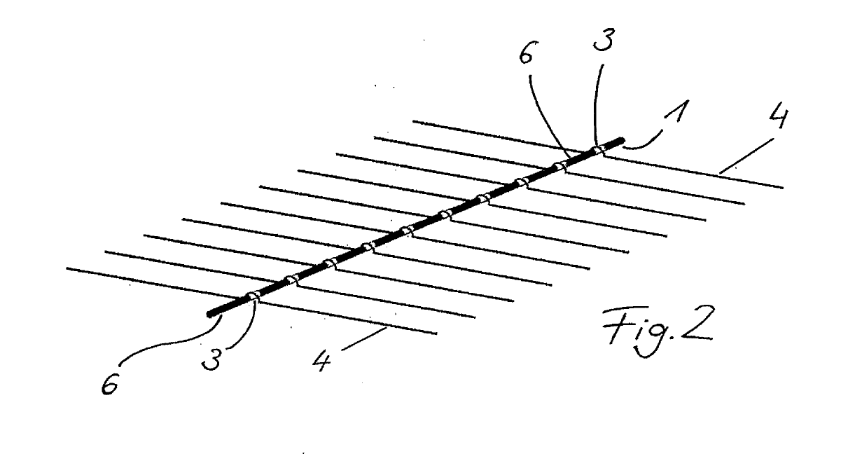

FIG. 2: in schematic form, a piezoelectric element which can be contacted with copper wires as electrically conductive connections; and

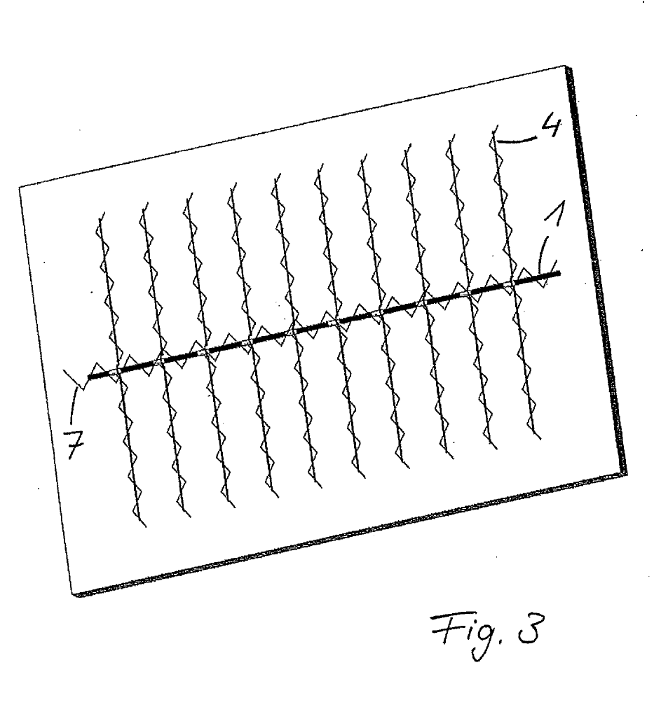

FIG. 3: a reinforced-fiber composite with a piezoelectric element stitched on.

In FIG. 1, a schematic arrangement of fibrous piezoelectric elements 1 of PZT which are arranged in parallel to one another is shown. Flexibly deformable copper wires, as electrically conductive connections 4, are likewise aligned in parallel to one another and perpendicular to the piezoelectric elements. They lie at contact points directly on the electrodes 3 of the piezoelectric elements 1 which are arranged at spacings from one another. Electric connector contacts 3 are thereby formed via which electric current can flow between piezoelectric elements 1 and electric connections 4. Two electric connections 4 arranged directly next to one another are connected to a respective different electric pole. In this respect, electrically conductive connections 4 of the same polarity are wired/connected to one another.

An arrangement as shown in FIG. 2 can thus be placed onto a previously produced fiber structure (shown in FIG. 1) and can be fastened by sewing with threads or yarn, preferably from the fiber material of the fiber structure. In this respect, threads twine around the piezoelectric elements 1, the electrically conductive connections 4 and threads or stitches of the fiber structure.

The seams should in this respect secure a fixing in all directions, in particular in the region of the knots where piezoelectric elements 1 and electrically conductive connections 4 (solid black lines) contact one another.

The fiber structure can be a fabric of fiber glass 2 in a known manner. The fibers 2 in this example have a circular cross-section. They are formed as a flat band with rounded edges and their flat sides contact the piezoelectric elements 1. The fibers 2 are in this respect made as rovings and form a hybrid yarn with polypropylene.

The fiber structure with piezoelectric elements 1 and electric connections 4 fastened thereto can then be inserted into a mold tool and the fibers 2 can be embedded as a matrix material in polypropylene at a temperature of 220° C. and at a pressure of 2 bar. The temperature is maintained over a period of 10 min. and the reinforced-fiber composite is then demolded and cooled to environmental temperature.

The structure of piezoelectric elements 1 and electrically conductive connections 4 shown in FIG. 1 was manufactured by weaving. In this respect, the fiber structure with its fibers 2 can be woven simultaneously with the copper wires and the piezoelectric elements 1. The piezoelectric elements 1 and the electrically conductive connections 4 of copper wire are then woven into the fabric. Reinforcement fibers 5, which can be woven as weft yarn with the piezoelectric elements 1 are present in parallel to the piezoelectric elements 1.

In FIG. 2, a possible electric contacting of piezoelectric elements 1 with copper wires as electrically conductive connections 4 are shown in simplified form and while omitting the representation of the fiber structure. As already mentioned, electrically conductive electrodes 3 are present at the surface of the piezoelectric elements 1. The insulating layer 6 can be removed at positions for the establishing of the electrically conductive connection and contacting between the piezoelectric element 1 and the copper wires forming the electrically conductive connections 4.

This technical situation is also indicated with the representation of FIG. 3. Here, a fibrous piezoelectric element 1 is again present at an example of a reinforced-fiber composite in accordance with the invention. A plurality of copper wires, as electrically conductive connections 4, are present in a parallel serial arrangement and at intervals from one another as well as aligned perpendicular to the piezoelectric element 1.

Both the piezoelectric element 1, as also the electrically conductive connections 4, are stitched to and fixed to a textile fabric in the form of a fiber structure by means of threads 7.

Fibers or a yarn with which the actual fiber structure is formed, for example glass fibers, are led through the regions between the piezoelectric element 1 and electrically conductive connections 4. The piezoelectric elements 1 and the copper wires as electrically conductive connections 4 can be fixed within the fiber structure by these threads before the embedding in a matrix material can be carried out. This can be carried out using a process such as described in the example for FIG. 1.

1. A fiber-reinforced composite acting as an actuator, as a sensor and/or as a generator, wherein at least one piezoelectric element (1) of fibers or yarn (2) is fixed and positioned within a fiber structure or by means of fibers or yarn at a fiber structure and a flexible, electrically conductive connection (4) which can be contacted from outside the fiber-reinforced composite is guided at and/or within the fiber structure to electrical connector contacts (3) of the at least one piezoelectric element; and
a piezoelectric element (1), electrically conductive connections (4) and the fiber structure are embedded in a matrix material.

2. A fiber-reinforced composite in accordance with claim 1, characterized in that the piezoelectric element(s) (1) is/are woven into the fiber structure, twisted therein, and/or is/are fastened thereat by a sewing or stitching connection.

3. A fiber-reinforced composite in accordance with claim 1, characterized in that electrically conductive connections (4) is/are woven into the fiber structure, twisted therein, inserted therein, and/or is/are fastened thereat by a sewing or stitching connection.

4. A fiber-reinforced composite in accordance with claim 1, characterized in that the fiber structure is formed as an areal textile fabric.

5. A fiber-reinforced composite in accordance with claim 1, characterized in that the piezoelectric element(s) is/are formed as a fiber.

6. A fiber-reinforced composite in accordance with claim 1, characterized in that a plurality of piezoelectric elements (1) are present in serial arrangement.

7. A fiber-reinforced composite in accordance with claim 1, characterized in that a plurality of fibrous piezoelectric elements (1) are jacketed by fibers and/or a material so that the piezoelectric elements (1) connected to one another in this manner form a correspondingly extended piezoelectric element.

8. A fiber-reinforced composite in accordance with claim 1, characterized in that piezoelectric elements (1) formed as hollow fibers are embedded in an electrically conductive matrix material and/or are fixed by means of electrically conductive fibers and an electrically conductive connection (4) is led to and/or through the hollow space of the respective hollow fiber and is electrically conductively contacted therein at the respective piezoelectric element (1).

9. A fiber-reinforced composite in accordance with claim 1, characterized in that (an) electrically conductive connection(s) (4) is/are positioned and electrically conductively fixed at connector contacts by means of fibers or yarn of the fiber structure.

10. A fiber-reinforced composite in accordance with claim 1, characterized in that the piezoelectric element(s) (1) is/are arranged in the fiber-reinforced composite in a plane outside the neutral fiber.

11. A method of manufacturing a fiber-reinforced composite in accordance with claim 1, characterized in that the at least one piezoelectric element (1) is fastened by fibers or yarn by means of a textile manufacturing process in the fiber structure or by a sewing or stitching connection at the fiber structure and electrically conductive connections (4) are led to electric connector contacts (3) present at the piezoelectric element(s) (1), and
the fiber structure prepared in this manner is subsequently embedded in a matrix material within a molding tool and the matrix material is hardened or completely polymerized.

12. A method in accordance with claim 11, characterized in that the fiber structure with a fixed piezoelectric element (1) and electrically conductive connections (4) is inserted into a molding tool and the matrix material is then injected or cast.

13. A method in accordance with claim 11, characterized in that at least two laminate layers are manufactured as intermediate products and subsequently the laminate layers are connected to one another with material continuity by hot pressing, with the at least two laminate layers having been manufactured by a fiber structure and a thermoplastic matrix material and in this respect at least one laminate layer being used into which at least one piezoelectric element (1) is integrated.

14. A method in accordance with claim 13, characterized in that, for the manufacture of a laminate layer as an intermediate product, a fiber structure is impregnated with a polymer, a hybrid yarn is used for the fiber structure and/or a polymer which is not completely hardened or polymerized is infiltrated into the fiber structure.

15. A method in accordance with claim 11, characterized in that at least one piezoelectric element (4) is introduced into at least one receiver formed at the textile fiber structure in the form of a loop or a pocket and is fixed at/in the fiber structure and the matrix material is subsequently hardened or completely polymerized.

16. A method in accordance with claim 11, characterized in that, for the manufacture, at least two fiber structures, in which at least one piezoelectric element is fixed at at least one fiber structure, are connected to one another using a textile process in a shape matched manner and/or with material continuity before the hardening or complete polymerization of the matrix material.
